(19) United States
(12) Patent Application Publication
(10) Pub. No.: US 2026/0170200 A1
(43) Pub. Date: Jun. 18, 2026

(54) SIMULATION SYSTEM AND METHOD FOR MATERIAL DEFORMATION

(71) Applicants: MULTIVERSE COMPUTING, S.L., Donostia - San Sebastian (ES); IKERLAN S.COOP, Arrasate (ES)

(72) Inventors: Mazen ALI, San Sebastian (ES); Aser CORTINES PEIXOTO NETO, Paris (FR); Siddhartha Emmanuel MORALES GUZMAN, San Sebastian (ES); Samuel Douglas PALMER, Toronto (CA); Samuel Mugel, Toronto (CA); Roman ORUS, Donostia - San Sebastian (ES); Mireia OLAVE IRIZAR, Donostia-San Sebastian (ES); Hodei USABIAGA CARREA, Donostia-San Sebastian (ES)

(21) Appl. No.: 18/999,968

(22) Filed: Dec. 23, 2024

(30) Foreign Application Priority Data
Dec. 13, 2024 (EP) 24383367.0

(51) Int. Cl. G06F 30/23

(52) U.S. Cl. CPC G06F 30/23

(57) ABSTRACT

A computer-implemented method for simulating and analyzing material deformations with principles of linear elasticity, comprising: splitting material properties of a material into pieces; decomposition of the geometry into simple domains and computing mesh-grid tensors for all dimensions for specifying a corresponding coordinate with a defining mesh-grid function; using the mesh-grid tensors for each simple domains that are defined for all available dimensions to compute components of a Jacobian, and mapping a reference element into a small element of each simple domain to compute the components all at once; processing stress and strain fields of the material, external forces applied thereto and test function equations over local elements through the Jacobian components; assembling stiffness TN-operators and mass TN-operators for each simple domain; stitching the stiffness TN-operators and the mass TN-operators together for enforcing continuity over interfaces; and applying a mass TN-operator to a predefined external force TN-vector.

### CLAIM OF PRIORITY

This application claims the benefit of priority to European Patent Application No. 24383367.0, filed on Dec. 13, 2024, which is incorporated herein by reference in its entirety.

### TECHNICAL FIELD

The disclosure relates to simulation method and system for analyzing material deformation based on quantum mechanics.

Specifically, but without limitation, the disclosure pertains to a method for tensor network-based material deformation analysis and/or simulation within the framework of linear elasticity which can be performed on at least one computer system that includes at least one computation unit

### BACKGROUND

Material simulations are essential computational tools extensively used in both academic research and industrial applications. Many manufacturers heavily rely on such tools to optimize product design and reduce time to market. Classically these simulations are performed by solving partial differential equation models with finite element methods. However, the large number of degrees of freedom in accurate simulations leads to a very high computational cost.

Tensor networks (TNs) were initially developed in quantum mechanics to efficiently describe otherwise intractable quantum systems. TNs are capable of exponential compression for problems that contain certain structures. TN methods have been successfully applied to differential equations in state of the art. Furthermore, these methods may be considered for industrially relevant problems such as material simulations. The industrial application of these methods can significantly improve computational performance.

Patent document EP3084632A1 explains multiscale modeling and simulation software products in a control system for a manufacturing process. It also describes finite element problems to determine an effect of the stimulus on the coarse scale mesh using a numerical technique for dimensional reduction of physical field variable/tensor problems by computing Eigenmodes of a transformed non-dispersive stiffness matrix. However, this system does not apply to quantum systems and does not address reducing computational costs while maintaining high accuracy.

As a result, all the problems listed above require innovation in the relevant field.

### SUMMARY

An objective of the disclosure, in accordance with some examples, is significantly reducing computational costs while maintaining high accuracy. Thus, the disclosure provides more efficient product development cycles, improved material properties, and a substantial reduction in time to market. The method applies tensor networks (TNs) to simulate material deformations within the framework of continuum mechanics.

Another objective of the disclosure, in accordance with some embodiments, is increasing the computation speed with quantum or quantum-implemented methods and/or systems that storing all components and manipulate in tensor network format with specified assembly process.

Another objective of the disclosure, in accordance with some embodiments, is splitting a grid-sized geometry into multiple pieces as a tensorized format and analyzing them with the TN-operators.

Another objective of the disclosure, in accordance with some embodiments, is computing the contribution of each node type combination to the global operators in a tensorized form using the TN-operators with the values with at least one computer or computing system.

Another objective of the disclosure, in accordance with some embodiments, is providing a simulation system for analyzing material deformation that can run on at least one computer that includes a processor or that can run on a quantum computer/processor or a simulator.

### BRIEF DESCRIPTION OF THE DISCLOSURE

The disclosure is related to simulation systems and methods for material deformation to fulfil one, some or all aims mentioned above and will be obtained from the following detailed description. The disclosure is also related to: data processing systems with means for carrying out the methods; computer program products comprising instructions which, when the program products are executed by at least one computing unit, cause the at least one computing unit to carry out the methods; and computer-readable data carrier having stored thereon the computer program products, which may be computer-readable non-transitory storage mediums in some examples.

In accordance with embodiments, a computer-implemented method is provided for simulating and analyzing material deformations with principles of linear elasticity using quantum or quantum-implemented methods. In this method many different material deformations can be analyzed. For example: metals like steel, copper, aluminum; curable polymers like epoxy, polycarbonate; composite materials, ceramics, concrete etc. The method performs on at least one computing system that includes at least one processor, and at least one storage unit or medium containing parameters related to the material properties of a predetermined material with grid size geometry, and predefined external forces in a TN-Vector format; and the method includes a step of splitting the material properties with the grid sized geometry into multiple pieces.

The method includes decomposition of the geometry into multiple simple domains and computing one or more mesh-grid tensors as TN-vectors for all dimensions for specifying a corresponding coordinate with defining mesh-grid function for any given input in the one or more mesh-grid tensors; using the one or more mesh-grid tensors for each simple domains that are defined for all available dimensions to compute components of a Jacobian and determinant of the Jacobian of an element transformation; and mapping a reference element into a small element of each simple domain to compute the components all at once using TN-operations; processing stress and strain fields of a predetermined material model, forces applied to the predetermined material model and predefined test function equations (i.e., test function equations that are defined on the at least one storage unit or medium) over local elements for stiffness and mass matrices through the Jacobian components of the step of computing the components; assembling the stiffness and mass operators for each simple domain; stitching stiffness and mass operators together for enforcing continuity over interfaces; and applying a mass TN-operator to the external force TN-vector.

In some embodiments of the disclosure, the method includes computing a contribution of each node type combination to the global operators in a tensorized form using TN-operators with the values of the step of assembling the stiffness and mass operators for each simple domain; which are representing each material piece.

In some embodiments of the disclosure, the method includes providing or defining boundary conditions of the material for the simulation. These boundary conditions can be a definition for which side of the material is “fixed” (clamped).

In some embodiments of the disclosure, the method includes applying the TN-shift operators to the contributions above to shift the indices to the correct position in the global TN-operator.

In some embodiments of the disclosure, the method includes applying the boundary conditions through a mask TN-operator.

In some embodiments of the disclosure, the method includes stitching stiffness and mass operators together for enforcing continuity over interfaces by applying Kronecker products and TN-concatenation operators.

In some embodiments of the disclosure, the method includes a domain stitching step for joining or which allows to join different quadrilaterals/hexahedrons (SDs), allowing the geometry to be more complex and having different constants. Many simulations in industry are for testing joints of two different materials.

In some embodiments of the disclosure, the method includes using an implementation preconditioner for maintaining stability for ultra-fine grids, which allows to increase the number of points in the discretization, solve the same system and maintain the desired precision, while small numerical errors can be amplified due to the properties of the system.

In some embodiments of the disclosure, the method includes implementing material and geometric non-linearities for providing full non-linear displacement-strain relation, when the system is big enough and second order deformations are no longer negligible. This implementation is deployable within tensor network methods since it only involves Hadamard product of tensors. In some examples, a system is big enough when forces are so large that the associated deformations are big enough such that they are not well represented by linear (i.e., first order) approximations. By way of example, in a linear stretch of a uniaxial bar, the second order relative stretch is very relevant for relative stretches approximately of at least 10% the size of the bar.

In some embodiments of the disclosure, the method includes conducting dynamic computation that involves (e.g., time-dependent loading) discretizing the time and solving the same linear system for each time step; therefore, the method can highly reduce this computational time. This computation only involves creating different stiffness matrices and solving them at different discretization steps, then only classical implementations could be needed for this part.

In some embodiments of the disclosure, the method includes solving the assembled system with DMRG (i.e., density matrix renormalization group) or AMEn (i.e., alternating minimal energy) TN-solvers.

In some embodiments of the disclosure, the method includes computation made by splitting simple domain into quadrilaterals or hexahedrons according to the dimension (2D or 3D) of the geometry.

In some embodiments of the disclosure, alternative materials can be analyzed and material properties may vary with the direction of measurement or depending on where the material is measured, e.g., wood, carbon fiber, non-homogeneous materials.

The protection scope of the disclosure is specified in the claims and cannot be limited to the description made for illustrative purposes in this brief and detailed description. It is clear that a person skilled in the art can present similar embodiments in the light of the above and following descriptions without departing from the main theme of the disclosure.

### BRIEF DESCRIPTION OF DRAWINGS

FIG. 1 represents some embodiments of the disclosure.

FIG. 2 represents some embodiments of the disclosure.

FIG. 3 illustrates in a flowchart that shows the steps of a method in accordance with some embodiments of the disclosure.

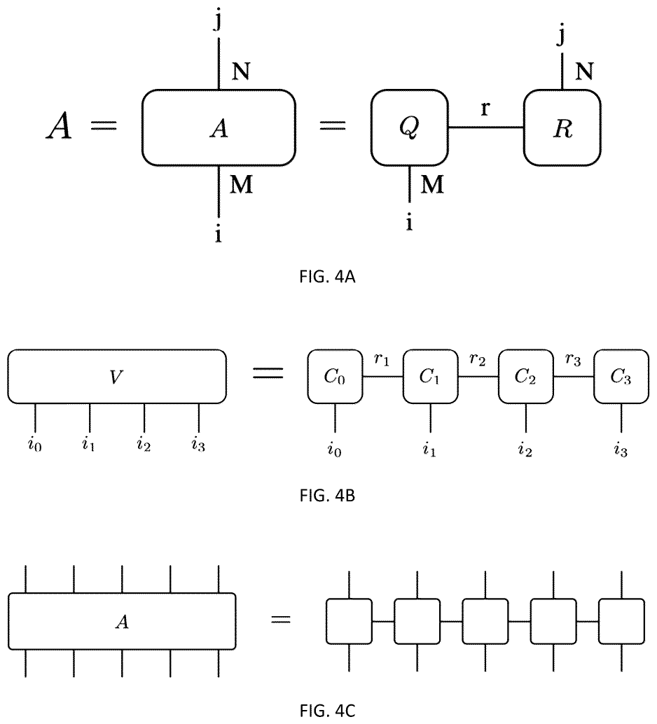

FIG. 4A shows an example QR-decomposition of matrix A.

FIG. 4B shows an example tensor train decomposition of a vector.

FIG. 4C shows an example tensor train decomposition of an operator.

FIG. 5 shows an example quadrilateral discretization with tensor networks.

FIG. 6A-6G shows the results of a method in accordance with some embodiments of the disclosure and includes comparisons with another simulation method known in the art.

### DESCRIPTION OF THE REFERENCE NUMBERS ILLUSTRATED IN THE FIGURES

10. Computing unit
100. Analyzing module
11. Storage medium
20. Data input module
21. Data initialization module
30. Geometry decomposition module
40. Mesh-grid computation module
50. Transformation/Mapping module
51. Mathematical computation module
60. TN-operator unit
61. Global TN-operator
62. TN-Shift operator
63. Mask TN-operator
64. TN-concatenation operator
65. Mass TN-operator
66. Stiffness TN-operator
S. System

### DETAILED DESCRIPTION

In this detailed description, a simulation system and a method for material deformation is described by means of examples only for clarifying the subject matter without any limitation of the scope of the disclosure.

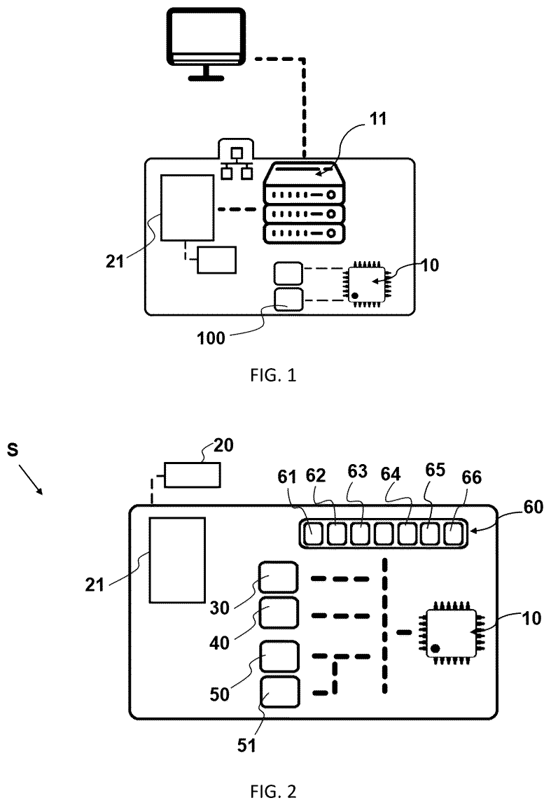

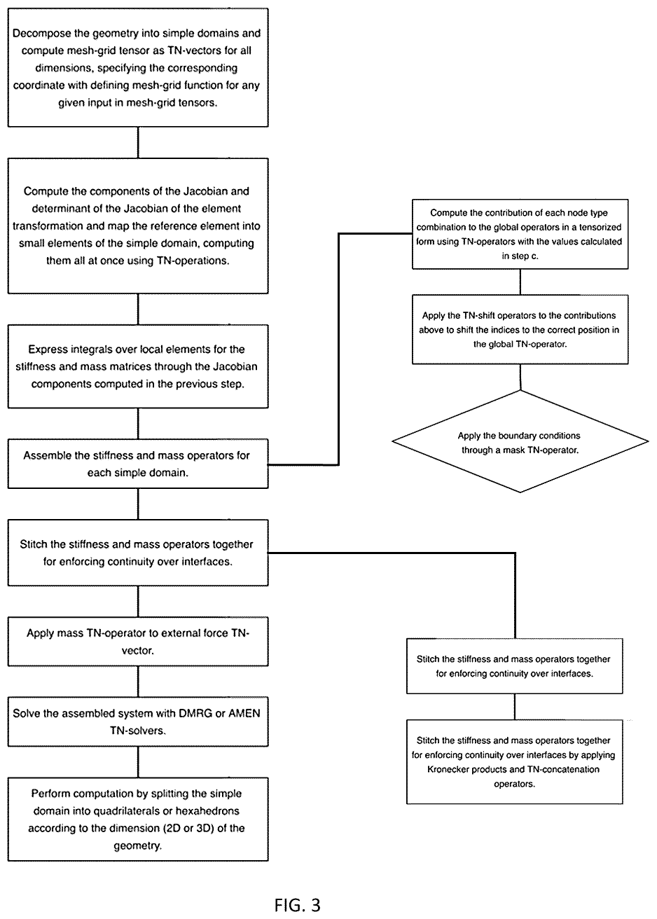

A computer-implemented method for simulating and analyzing material deformations with principles of linear elasticity uses at least one computing system (S), such as, e.g., the system shown in FIG. 1 and/or FIG. 2. The at least one computing system (S) includes at least one computing unit (10) and at least one storage medium (11). The at least one storage medium (11) comprises: parameters that are related to material properties of a predetermined material where the material properties have a grid size geometry; and predefined external forces in TN-Vector format. The parameters and/or the predefined external forces may be already stored in the at least one storage medium (11), received from a remote device or system (such as, e.g., at least one sensor, at least one computing device, etc.) through a communications channel, be manually input through user input means, etc.

The computer-implemented method may provide, upon simulating and/or analyzing material deformations, outputs such as data representative of deformations of the material for a given set of input conditions (e.g., forces, material properties, etc.). In some cases, said outputs or data may be provided for use by a computing device or by a user, for example, the outputs or data may be displayed in several ways. By way of example, the method could connect to a computer display and provide visual graphics of the material with the corresponding deformations. By way of example, the method may output a mathematical amount of deformations, which could be used by a technician for further computational analysis if required.

The computer-implemented method includes a step of splitting the grid sized geometry into multiple pieces and for analyzing material deformations; decomposing the geometry into multiple simple domains and computing a mesh-grid tensor as TN-vectors for all dimensions for specifying the corresponding coordinate with defining mesh-grid function for any given input in mesh-grid tensors; using mesh-grid tensors for each simple domains that defined for all available dimensions; computing the components of the Jacobian and determinant of the Jacobian of the element transformation and mapping the reference element into small element of each simple domain to compute them all at once with using TN-operations; processing stress and strain fields within the material, forces applied to the material and test function equations that are defined on the at least one storage medium (11) over local elements for the stiffness and mass matrices through the Jacobian components that computed in a previous step; assembling stiffness TN-operators (66) and mass TN-operators (65) for each simple domain; stitching the stiffness TN-operators (66) and the mass TN-operators (65) together for enforcing continuity over interfaces; applying a mass TN-operator unit (60) to external force TN-vector.

The method proceeds, in some embodiments, in two stages with the at least one computing unit (10) as assembling a virtual system using tensor network operators and representing a discrete model, and simulating the results that are related to an applied force on the material.

In the computer-implemented method, input definitions are grid size, geometry, material parameters (type, stiffness etc.), boundary conditions (clamped sides that are used when the force is applied on the material in the simulations), and external forces definition variables for every simulation. These inputs can be entered into the at least one computing system (S). for example, as one or more variables for each simulation or analysis. In some embodiments of the disclosure, material parameters are used for providing one or more Cauchy stress tensors, which describes the materials infinitesimal response to stresses.

The computer-implemented method defines an assembly in a tensorized format. With this step, the assembly is created by decomposition of the geometry into simple domains and computing mesh-grid tensor as TN-vectors for all dimensions for specifying the corresponding coordinate with defining mesh-grid function for any given input (e.g., one or more inputs) in mesh-grid tensors. Computational domains extended from one dimension to two and three
dimensions (2D or 3D). The computational domain is split into quadrilaterals or [0045] hexahedrons for defining the dimensions (quadrilaterals for 2D, hexahedrons for 3D). On each piece, the method assembles a local system directly represented with a TN operator with the TN-operator unit (60). The local TN operators (which are the stiffness TN-operators (66) and/or the mass TN-operators (65)) are then combined into a global TN-operator (61), which represent discrete differential equations on this domain, including the boundary conditions which is a fixation status of the material. Precision may be obtained through an exponential discretization of the domain and linear approximation functions that may be enough for exponential compression.

Unlike finite elements, simple domains are larger subdomains that simplify complex geometries. Decomposition to the simple domain process allows for flexible meshing and handling of intricate shapes, while finite element analysis is applied within each single domain. All elements in the analysis of each simple domain (SD) are quadrilaterals (2D) or hexahedrons (3D) with piecewise bilinear or trilinear basis functions.

A data input module (20) and a data initializing module (21) evaluate and/or convert the external forces as TN-Vector format. Such evaluation and/or conversion is made with the support of the at least one computing unit (10) and, in some embodiments, the evaluation and/or conversion is based on a TN-cross approximation method.

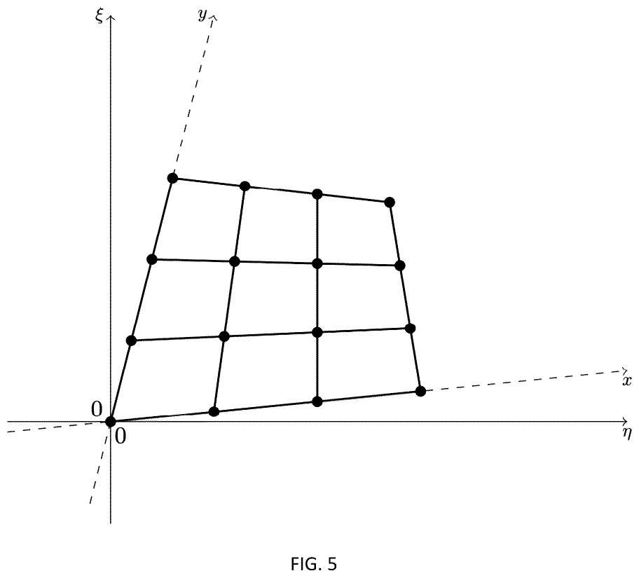

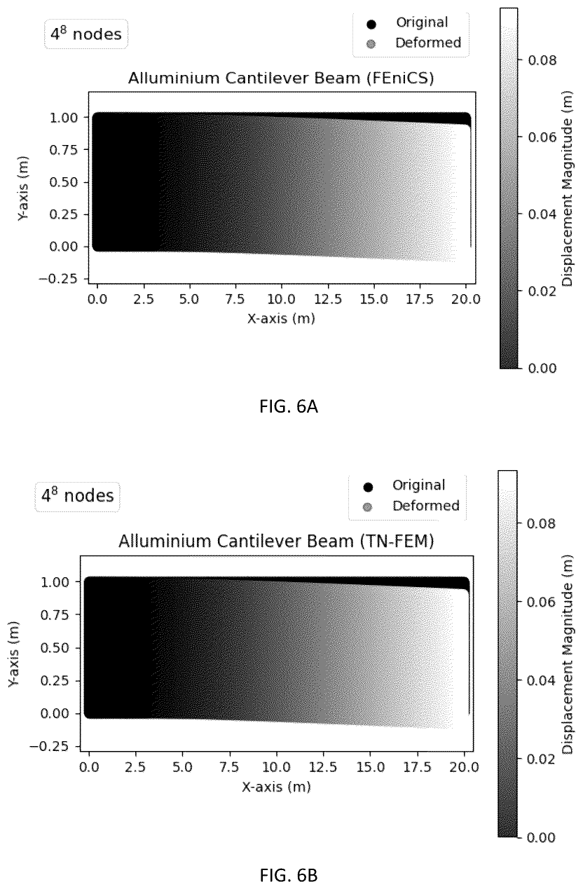

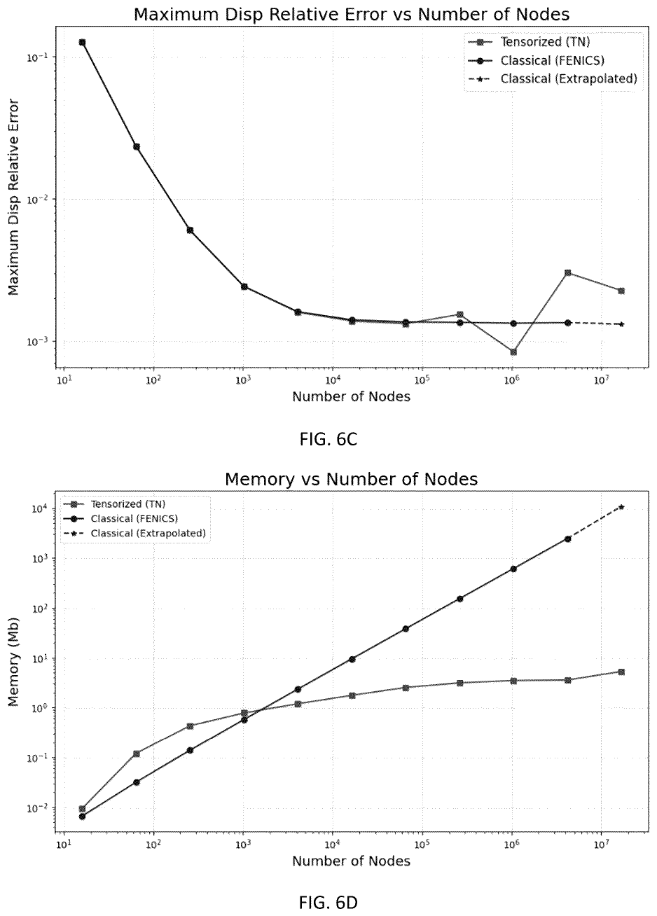

FIGS. 4A, 4B and 4C show an example decomposition of a matrix and a tensor train of a vector with an operator.

$$\begin{matrix}A = QR , & A ∈ {ℝ}^{M \times N} , & Q ∈ {ℝ}^{M \times r} , & R ∈\end{matrix} {ℝ}^{r \times N} .$$

Tensor trains (TTs) can also be applied to matrices and vectors, a process commonly referred to as the quantics tensor train (QTT).

A mesh-grid computation module (30) computes one or more mesh-grid tensors as TN-vectors that specifies the corresponding coordinate for any above-mentioned inputs for all dimensions. For example, if the given coordinates are x, y and z, the mesh-grid tensors return X (x, y, z)=x, Y (x, y, z)=y and Z (x, y, z)=z.

In some embodiments, the above mentioned construction of X, Y and Z can be performed exactly with small TN-ranks. Thus, the method provides small storage and short compression time (Logarithmic in grid size).

In some embodiments, the method includes a computation made for a same time for each material piece, which are represented as simple domains with the mesh-grid tensors (X, Y, Z) with the definition of Jacobian using tensor network operations. Jacobian components computation, element transformation managed with the mapping the reference element. In some embodiments, the mentioned reference element (mapping) is [−1, 1]² in the 2D and [−1, 1]³ in the 3D for any element of the simple domain. These components depend linearly on the mesh-grid functions X, Y and Z. This, in turn, provides computation at same time for all material pieces that have been defined in different simple domains.

According to some alternative embodiments of the disclosure, a 3D implementation is extension of the 2D implementation, here the mesh-grid tensors are built in the same way maintaining a very low rank. The Jacobian components are based on those mesh-grid tensors; therefore, their construction is straightforward. All the following steps are the same but just with an extra dimension to be encoded in a tensor format.

In some embodiments, the computer-implemented method includes the assembly of a discrete model system, which may be performed in a tensorized format, wherein a computational domain is split into pieces. Local tensor network (TN) operators are assembled on each piece directly in a TN format, and the local TN operators are combined into a global TN operator representing the discrete model system including boundary conditions on the computational domain. The assembled system is solved using TN solvers, with regular recompression of solution TNs to maintain computational efficiency by controlling TN ranks and complexity.

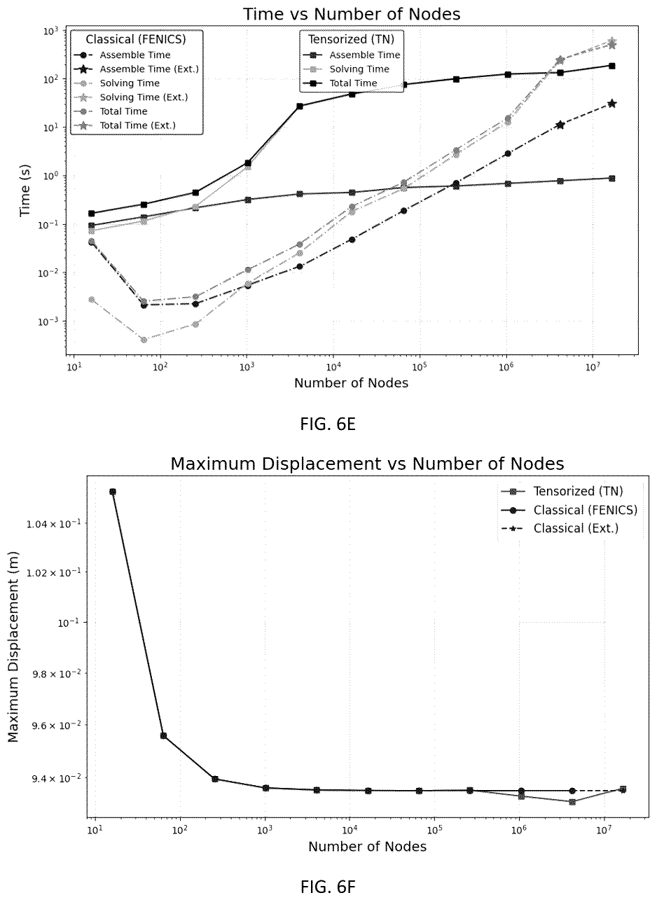

FIG. 5 shows an example quadrilateral discretization in powers with the tensor networks. According to the example, it is shown 4² discretization, i.e., this example shows 16 grid points including boundary points, 32 degrees of freedom (16 for each vector field component) and 9 elements.

In some embodiments, the computer-implemented method includes an assembly process that comprises a tensorized definition for all input and element. Each component of the vector fields represented as a tensor train (TT) like FIG. 4B with, e.g., the following equation.

$$a ( u , v ) := {\int }_{Ω} σ ( u ( x ) ) : ε ( v ( x ) ) diffx = L ( v ) := {\int }_{Ω} f ( x ) \cdot v ( x ) diffx$$

In some embodiments, a stiffness matrix A and force vector f represented as TT-operator, like in FIG. 4C, for a configuration for the at least one computing unit (10).

For calculating a Jacobian, the computer-implemented method may include a similar calculation. In this sense, the inverse (detJ)^{{-1}} with TN-cross approximation may be conducted.

A difference between the disclosed computer-implemented method (and system) and known methods is that a tensorized assembly lies within the treatment of the Jacobians of the element transformations. According to the disclosure, all components are stored and manipulated in a TN format, which requires a specialized assembly process.

$${J}_{\{ ( i , j ) \}} ( ξ ) = {J}_{\{ ( 0 , 0 ) \}} ( ξ ) + i ( {J}_{\{ ( 1 , 0 ) \}} ( ξ ) - {J}_{\{ ( 0 , 0 ) \}} ( ξ ) ) + j ( {J}_{\{ ( 0 , 1 ) \}} ( ξ ) - {J}_{\{ ( 0 , 0 ) \}} ( ξ ) )$$

A similar expression for the determinant may be provided. Construction of X and Y (for 2D) may also be conducted such that

$$X ( i , j ) = i \qquad and \qquad Y ( i , j ) = j$$

defines a tensorized mesh-grid function. The construction of X and Y is straightforward and has a tensor rank of at most second due to above expression since each component of the Jacobian is an affine-linear function in X and Y and construct a TT for each Jacobian component with the same ranks as X and Y. Thus, it provides

$$J ( ξ ) = ( \begin{matrix}{J}_{\{ ( 1 , 1 ) \}} ( ξ ) & {J}_{\{ ( 2 , 2 ) \}} ( ξ ) \\ {J}_{\{ ( 2 , 1 ) \}} ( ξ ) & {J}_{\{ ( 2 , 2 ) \}} ( ξ )\end{matrix} )$$

where each component Jₖₗ(ξ) is a TT representing the values of that component of the Jacobian, evaluated at & E for all elements also for the det J.

All the above computations for/and det J are preferably numerically exact and represented with low-rank TTs. However, the inverse above Jacobians equation must be expressed explicitly through the components of/to apply TT operations (TT-cross interpolation). The inverse of J can be expressed through the adjugate of J and the inverse determinant (det J)⁻¹. This means computing the TT representation (det J)⁻¹ of the component-wise inverse of det J. In one embodiment of the invention TT-cross routines used for doing it.

The computer-implemented method and the system (S) simulate stress and strain fields within the material which are defined as simple domains, forces applied to the material and test function equations that defined on the at least one storage medium (11) over local elements for the stiffness and mass matrices through the Jacobian components. This calculation made by the at least one computing unit (10).

According to the 2D analysis, each element/material has four corners (as shown, for example, in FIG. 5), and to each of those corners, two basis functions can be associated (or three in 3D) with one basis function for each coordinate direction of the vector fields as. Thus, provides eight possible basis functions per element/material in total.

The computer-implemented method and the system (S) which runs said method include computing or at least one mathematical computation module (51) for processing stress and strain fields within the material, and computing the stiffness operator for pairs of basis functions a(φⱼ, φᵢ). Thus, the computation gives a total of 64 possible pairs that expressed each of these in terms of the tensorized Jacobian components involved.

In some embodiments, each of the terms added to the global stiffness operator A.

Forces applied to the material and test function equations with the parameters provided from a TN-operator unit (60) provide representation of force vector values at all grid points.

The system (S) illustrated, e.g., in FIGS. 1 and/or 2, is for simulating and analyzing material deformations with principles of linear elasticity, such as according to the aforesaid computer-implemented method.
The system (S) includes at least one data input module (20) and data initialization module (21) that create tensorized definitions for parameters that are related to the material properties with grid size geometry and predefined external forces in TN-Vector format; at least one geometry decomposition module (30) that decomposes the geometry into simple domain and splits the grid sized geometry into multiple pieces; at least one mesh-grid computation module (40) that specifies the corresponding coordinates which can be received from data initialization module (21); at least one transformation/mapping module (50) that can work together with the at least one computing unit (10) and that computes the component element transformation and mapping the reference element for the dimensions and at least one TN-operator unit (60) that computes mesh-grid functions into the at least one computing unit (10); at least one mathematical computation module (51) that processes stress and strain fields within the material, the forces applied to the material and test function equations using with the parameters provided by the at least one TN-operator unit (60); and also includes
At least one global TN-operator (61) that computes the contribution of each note types as a tensorized from with the values received from at least one TN-operator unit (60) and the at least one mathematical computation module (51);
At least one TN-shift operator (62) that shifts the indices to the correct position in the at least one global TN operator (61);
At least one mask TN-operator (63) that applies boundary conditions, which are a definition of the material's fixation status;
At least one TN-concatenation operator (64) that stitches stiffness and mass operators together;
At least one mass TN-operator that simulates with the external force TN-vector received from data initialization module (21).

The system (S) also includes at least one analyzing module (100), that is pre-defined on the at least one computing unit (10), and simulates the external tensorized forces effects to the assembled tensorized virtual system, which includes tensorized material that is stored on the at least one storage medium (11).

In some embodiments, a mass matrix can be assembled analogously as a mass TN-operator (65) to stiffness TN-operator (66) with the TN-concatenation operator (64) of the system (S).

In some embodiments, the system (S) includes at least one global TN-operator (61) that computes the contribution of each note types as a tensorized from with the values received from the at least one TN-operator unit (60) and the at least one mathematical computation module (51).

In some embodiments, the system (S) includes at least one TN-shift operator (62) that shifts a position of indices in the at least one global TN operator (61). Particularly, the at least one TN-shift operator (62) shifts the indices to the correct position in the at least one global TN operator (61).

In some embodiments, the system (S) includes at least one mask TN-operator (63) that applies boundary conditions that are defined as TN format at the data initializing module (21) for simulation and analysis.

In some embodiments, the system (S) includes at least one mass TN-operator that simulates with the external force TN-vector that received from the data initialization module (21) for simulation.

In some embodiments, the computer-implemented method and the system (S) includes or performs a compression step which provides exponential speedups for the simulations.

In the system (S), modules and operators as described above are configured to conduct the functions described.

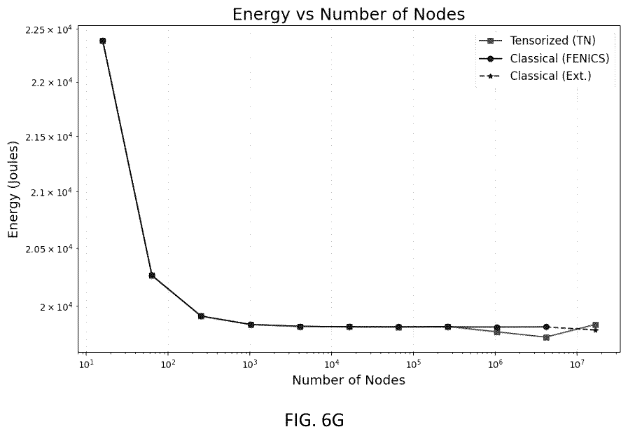

FIGS. 6A and 6B shows a test example for a material which is a 2D cantilever beam made of aluminum with 20 m length, 1 m width.

The simulation conditions are: Young modulus of E=68 GPa. Poisson's ratio of v=0.33, density ρ=2700 kgm⁻³, fixed on one side with 48 grid points.

Comparison made between FEniCS (Open source calculation method that can run on a computing system) and a computer-implemented method according to some embodiments of the disclosure: FIG. 6C shows relative errors for the maximum displacement between both methods; FIG. 6D shows memory needs to store the stiffness matrix, force vector and the displacement vector with the logarithmic scale. This result shows exponential compression of the data with better results; FIG. 6E shows solving time and total time; and FIG. 6F and FIG. 6G show displacement and energy comparisons.

The method and system of the present disclosure can be applicable to any computation system with configurations as set out above. The at least one computing unit (10) executes the tensor network-based material deformation analysis/simulation with the method and analyzes material deformation based on quantum mechanics within the framework of linear elasticity and performs material deformation analysis/simulation and creates results to the user(s).

Although specific examples are described herein, it will be evident that various modifications and changes may be made to these examples without departing from the broader spirit and scope of the disclosure. Accordingly, the specification and drawings are to be regarded in an illustrative rather than a restrictive sense. The accompanying drawings that form a part hereof show by way of illustration, and not of limitation, specific examples in which the subject matter may be practiced. The examples illustrated are described in sufficient detail to enable those skilled in the art to practice the teachings disclosed herein. Other examples may be utilized and derived therefrom, such that structural and logical substitutions and changes may be made without departing from the scope of this disclosure. This detailed description, therefore, is not to be taken in a limiting sense, and the scope of various examples is defined only by the appended claims, along with the full range of equivalents to which such claims are entitled.

Such examples of the inventive subject matter may be referred to herein, individually or collectively, by the term “example” or “embodiment” merely for convenience and without intending to voluntarily limit the scope of this application to any single example or concept if more than one is in fact disclosed. Thus, although specific examples have been illustrated and described herein, it should be appreciated that any arrangement calculated to achieve the same purpose may be substituted for the specific examples shown. This disclosure is intended to cover any and all adaptations or variations of various examples. Combinations of the above examples, and other examples not specifically described herein, will be apparent to those of skill in the art upon reviewing the above description.

Some portions of the subject matter discussed herein may be presented in terms of algorithms or symbolic representations of operations on data stored as bits or binary digital signals within a machine memory (e.g., a computer memory). Such algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or any suitable combination thereof), registers, or other machine components that receive, store, transmit, or display information. Furthermore, unless specifically stated otherwise, the terms “a” and “an” are herein used, as is common in patent documents, to include one or more than one instance. As used herein, the conjunction “or” refers to a non-exclusive “or,” unless specifically stated otherwise.

Unless the context clearly requires otherwise, throughout the description and the claims, the words “comprise,” “comprising,” “include,”, “including,” and the like are to be construed in an inclusive sense, as opposed to an exclusive or exhaustive sense, e.g., in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words using the singular or plural number may also include the plural or singular number, respectively. The word “or” in reference to a list of two or more items, covers all of the following interpretations of the word: any one of the items in the list, all of the items in the list, and any combination of the items in the list.

Although some examples may include a particular sequence of operations, the sequence may in some cases be altered without departing from the scope of the present disclosure. For example, some of the operations depicted may be performed in parallel or in a different sequence that does not materially affect the functions as described in the examples. In other examples, different components of an example device or system that implements an example method may perform functions at substantially the same time or in a specific sequence.

As used herein, the term “processor” may refer to any one or more circuits or virtual circuits (e.g., a physical circuit emulated by logic executing on an actual processor) that manipulates data values according to control signals (e.g., commands, opcodes, machine code, control words, macroinstructions, etc.) and which produces corresponding output signals that are applied to operate a machine. A processor may, for example, include at least one of a Central Processing Unit (CPU), a Reduced Instruction Set Computing (RISC) Processor, a Complex Instruction Set Computing (CISC) Processor, a Graphics Processing Unit (GPU), a Digital Signal Processor (DSP), a Tensor Processing Unit (TPU), a Neural Processing Unit (NPU), a Vision Processing Unit (VPU), a Machine Learning Accelerator, an Artificial Intelligence Accelerator, an Application Specific Integrated Circuit (ASIC), a Field Programmable Gate Array (FPGA), a Radio-Frequency Integrated Circuit (RFIC), a Neuromorphic Processor, a Quantum Processor, or any combination thereof. A processor may be a multi-core processor having two or more independent processors (sometimes referred to as “cores”) that may execute instructions contemporaneously. Multi-core processors may contain multiple computational cores on a single integrated circuit die, each of which can independently execute program instructions in parallel. Parallel processing on multi-core processors may be implemented via architectures like superscalar, VLIW, vector processing, or SIMD that allow each core to run separate instruction streams concurrently. A processor may be emulated in software, running on a physical processor, as a virtual processor or virtual circuit. The virtual processor may behave like an independent processor but is implemented in software rather than hardware.

The various operations of example methods described herein may be performed, at least partially, by one or more processors that are temporarily configured (e.g., by software) or permanently configured to perform the relevant operations. Whether temporarily or permanently configured, such processors may constitute processor-implemented modules/components that operate to perform one or more operations or functions. The modules/components referred to herein may, in some examples, comprise processor-implemented modules/components.

Similarly, the methods described herein may be at least partially processor-implemented. For example, at least some of the operations of a method may be performed by one or more processors or processor-implemented modules/components. The performance of certain of the operations may be distributed among the one or more processors, not only residing within a single machine, but deployed across a number of machines. In some examples, the processor or processors may be located in a single location (e.g., within a home environment, an office environment, or a server farm), while in other examples the processors may be distributed across a number of locations.

Examples may be implemented in digital electronic circuitry, or in computer hardware, firmware, or software, or in combinations of them. Examples may be implemented using a computer program product, e.g., a computer program tangibly embodied in an information carrier, e.g., in a machine-readable medium for execution by, or to control the operation of, data processing apparatus, e.g., a programmable processor, a computer, or multiple computers.

A computer program can be written in any form of programming language, including compiled or interpreted languages, and it can be deployed in any form, including as a standalone program or as a module, subroutine, or other unit suitable for use in a computing environment. A computer program can be deployed to be executed on one computer or on multiple computers at one site or distributed across multiple sites and interconnected by a communication network.

1. A computer-implemented method for simulating and analyzing material deformations with principles of linear elasticity, the method comprising:
splitting material properties of a predetermined material into multiple pieces, wherein the material properties have a grid sized geometry;
decomposition of the geometry into multiple simple domains and computing one or more mesh-grid tensors as tensor network, TN, vectors for all dimensions for specifying a corresponding coordinate with a defining mesh-grid function for any given input in the one or more mesh-grid tensors;
using the one or more mesh-grid tensors for each simple domains that are defined for all available dimensions to compute components of a Jacobian and a determinant of the Jacobian of an element transformation, and mapping a reference element into a small element of each simple domain to compute the components all at once using TN-operations;
processing stress and strain fields of the predetermined material, predefined external forces applied to the predetermined material and predefined test function equations over local elements for stiffness and mass matrices through the Jacobian components, the predefined external forces being defined in TN vector format;
assembling stiffness TN-operators and mass TN-operators for each simple domain;
stitching the stiffness TN-operators and the mass TN-operators together for enforcing continuity over interfaces; and
applying a mass TN-operator to a predefined external force TN-vector related to the predetermined material.

2. The computer-implemented method of claim 1, wherein assembling the stiffness and mass TN-operators for each simple domain, which are representing each material pieces, comprises computing a contribution of each node type combination to global operators in a tensorized form by processing stress and strain fields of the predetermined material with the TN-operators using the values calculated and mapped into small element of each simple domain with components of the Jacobian and determinant of the Jacobian of the element transformation.

3. The computer-implemented method of claim 2, wherein applying the TN-shift operators to the contribution of each node type combination to global operators in a TN-vector format to shift the indices to position in the global TN-operator.

4. The computer-implemented method of claim 1, further comprising applying boundary conditions to the predetermined material defined as a grid sized geometry through a mask TN-operator.

5. The computer-implemented method of claim 1, wherein the step of stitching stiffness and mass TN-operators together for enforcing continuity over interfaces comprises applying Kronecker products and TN-concatenation operators.

6. The computer-implemented method of claim 1, further comprising solving an assembled system with DMRG or AMEn TN-solvers.

7. The computer-implemented method of claim 1, further comprising computing by splitting simple domain into quadrilaterals or hexahedrons according to a dimension of the geometry.

8. The computer-implemented method of claim 1, wherein the material properties of the predetermined material with the grid size geometry and the predefined external forces in TN format are stored in at least one storage medium.

9. A system for simulating and analyzing material deformations with principles of linear elasticity, the system comprising:
at least one data input module and data initialization module configured to create tensorized definitions for parameters related to material properties of a predetermined material with grid sized geometry, and predefined external forces in tensor network, TN, Vector format;
at least one geometry decomposition module configured to decompose the geometry into simple domain and split the grid sized geometry into multiple pieces;
at least one mesh-grid computation module configured to specify corresponding coordinates receivable from the data initialization module;
at least one transformation/mapping module configured to compute a component element transformation and map a reference element for the dimensions;
at least one TN-operator unit configured to compute mesh-grid functions into a computing unit of the system;
at least one mathematical computation module configured to process stress and strain fields within the predetermined material, forces applied to the predetermined material and test function equations using parameters provided by the least one TN-operator unit;
at least one global TN-operator configured to compute a contribution of each note types as a tensorized form with values receivable from the at least one TN-operator unit and the at least one mathematical computation module;
at least one TN-shift operator configured to shift indices to a correct position in the at least one global TN-operator;
at least one mask TN-operator configured to apply boundary conditions, which are a definition of the predetermined material's fixation status;
at least one TN-concatenation operator configured to stitch stiffness and mass operators together;
at least one mass TN-operator configured to simulate an external force TN-vector receivable from the data initialization module; and
at least one analyzing module configured to simulate external tensorized forces effects to the assembled tensorized virtual system, which includes a tensorized material stored on at least one storage medium of the system.

10. The system of claim 9, wherein the at least one mesh-grid computation module is further configured to create mesh grid tensors with TN-ranks for providing small storage and short compression time.

11. The system of claim 10, wherein the TN-ranks are small TN-ranks.

12. The system of claim 9, further comprising at least one classical computer that includes a processor configured to initialize the data and at least one quantum device communicating with the at least one classical computer and including at least one quantum processor as a computing unit.

13. The system of claim 12, further comprising the at least one quantum device.

14. The system of claim 9, wherein the system is configured, upon reception of the material properties of the predetermined material with the material having the grid sized geometry, to at least carry out the following:
split the material properties of the predetermined material into the multiple pieces;
decompose the geometry into multiple simple domains and compute one or more mesh-grid tensors TN-vectors for all dimensions for specifying a corresponding coordinate with a defining mesh-grid function for any given input in the one or more mesh-grid tensors;
use the one or more mesh-grid tensors for each simple domains that are defined for all available dimensions to compute components of a Jacobian and a determinant of the Jacobian of an element transformation, and map a reference element into a small element of each simple domain to compute the components all at once using TN-operations;
process stress and strain fields of the predetermined material, predefined external forces applied to the predetermined material and predefined test function equations over local elements for stiffness and mass matrices through the Jacobian components, the predefined external forces being defined in TN vector format;
assemble the stiffness TN-operators and mass TN-operators for each simple domain;
stitch the stiffness TN-operators and the mass TN-operators together for enforcing continuity over interfaces; and
apply the mass TN-operator to a predefined external force TN-vector related to the predetermined material.

15. The system of claim 9, wherein assembly of the stiffness and mass TN-operators for each simple domain, which are representing each material pieces, comprises computing a contribution of each node type combination to global operators in a tensorized form by processing stress and strain fields of the predetermined material with the TN-operators using the values calculated and mapped into small element of each simple domain with components of the Jacobian and determinant of the Jacobian of the element transformation.

16. The system of claim 9, wherein application of the TN-shift operators to the contribution of each node type combination to global operators in a TN-vector format to shift the indices to position in the global TN-operator.

17. The system of claim 9, wherein the at least one storage medium is configured to store the material properties of the predetermined material with the grid size geometry and the predefined external forces in TN format.

18. A computer-readable non-transitory storage comprising instructions that, when executed by processing circuitry, cause the processing circuitry to at least perform:
splitting material properties of a predetermined material into multiple pieces, wherein the material properties have a grid sized geometry;
decomposition of the geometry into multiple simple domains and computing one or more mesh-grid tensors as tensor network, TN, vectors for all dimensions for specifying a corresponding coordinate with a defining mesh-grid function for any given input in the one or more mesh-grid tensors;
using the one or more mesh-grid tensors for each simple domains that are defined for all available dimensions to compute components of a Jacobian and a determinant of the Jacobian of an element transformation, and mapping a reference element into a small element of each simple domain to compute the components all at once using TN-operations;
processing stress and strain fields of the predetermined material, predefined external forces applied to the predetermined material and predefined test function equations over local elements for stiffness and mass matrices through the Jacobian components, the predefined external forces being defined in TN vector format;
assembling stiffness TN-operators and mass TN-operators for each simple domain;
stitching the stiffness TN-operators and the mass TN-operators together for enforcing continuity over interfaces; and
applying a mass TN-operator to a predefined external force TN-vector related to the predetermined material.

19. The computer-implemented method of claim 1, wherein assembling the stiffness and mass TN-operators for each simple domain, which are representing each material pieces, comprises computing a contribution of each node type combination to global operators in a tensorized form by processing stress and strain fields of the predetermined material with the TN-operators using the values calculated and mapped into small element of each simple domain with components of the Jacobian and determinant of the Jacobian of the element transformation.

20. The computer-implemented method of claim 1, wherein applying the TN-shift operators to the contribution of each node type combination to global operators in a TN-vector format to shift the indices to position in the global TN-operator.
